(19) United States
(12) Patent Application Publication
(10) Pub. No.: US 2020/0243576 A1
(43) Pub. Date: Jul. 30, 2020

(54) THIN FILM TRANSISTOR, METHOD FOR FABRICATING THE SAME, ARRAY SUBSTRATE, AND DISPLAY DEVICE

(71) Applicants: BOE Technology Group Co., Ltd., Beijing (CN); Hefei BOE Optoelectronics Technology Co., Ltd., Hefei, Anhui (CN)

(72) Inventors: Kui GONG, Beijing (CN); Xianxue DUAN, Beijing (CN); Jilong LI, Beijing (CN)

(21) Appl. No.: 15/768,225

(22) PCT Filed: Nov. 11, 2017
(86) PCT No.: PCT/CN2017/110441

§ 371 Date: Apr. 13, 2018

(30) Foreign Application Priority Data
May 8, 2017 (CN) 201710318885.3

(51) Int. Cl. H01L 27/12; H01L 29/66; H01L 29/24; H01L 29/786

(52) U.S. Cl. CPC H01L 27/1288; H01L 27/1225; H01L 29/66765; H01L 29/78669; H01L 29/66969; H01L 29/7869; H01L 29/24

(57) ABSTRACT

Disclosed are a thin film transistor, a method for fabricating the same, an array substrate, and a display device. The method of this disclosure includes: fabricating an anti-etching layer pattern on an active layer, wherein the anti-etching layer pattern is doped with an electrically conductive medium; etching away an area of the active layer, which is not covered with the anti-etching layer pattern, to form an active layer pattern, and reserving the anti-etching layer pattern; and fabricating a source and a drain of the thin film transistor.

This application is a National Stage of International Application No. PCT/CN2017/110441, filed Nov. 10, 2017, which claims the benefit of Chinese Patent Application No. 201710318885.3, filed with the Chinese Patent Office on May 8, 2017 and entitled “A thin film transistor, a method for fabricating the same, an array substrate, and a display device”, which are hereby incorporated by reference in their entireties.

### FIELD

The present disclosure relates to the field of communications, and particularly to a thin film transistor, a method for fabricating the same, an array substrate, and a display device.

### BACKGROUND

As the sciences and technologies are advancing, a flat panel display device has been widely applied to our daily life in place of a cumbersome Cathode Ray Tube (CRT) display device. At present, a common flat panel display device includes a Solution Crystal Display (LCD) device and an Organic Light-Emitting Diode (OLED) display device. A Thin Film Transistor (TFT) is crucial to the solution crystal display device and the OLED display device with a large size, and related directly to a developing high-performance flat plat display device.

In the related art, thin film transistors in the industry generally include amorphic silicon thin film transistors, poly-silicon thin film transistors, monocrystalline thin film transistors, etc. As the technologies are advancing, there have emerged metal oxide thin film transistors advantageous in the high mobility of carriers so that the thin film transistors can be made small, and there will be a higher resolution and a better display effect of the flat plat display device; and also the metal oxide thin film transistors are advantageous in less characteristic non-uniformity, lower material and process costs, low process temperature, the applicability of a spin-coating process thereto, high transparency, a large band gap, etc., and thus have been widely favored in the industry.

### SUMMARY

This disclosure provides a thin film transistor, a method for fabricating the same, an array substrate, and a display device.

An embodiment of this disclosure provides a method for fabricating a thin film transistor, the method including: fabricating an anti-etching layer pattern on an active layer, wherein the anti-etching layer pattern is doped with an electrically conductive medium; etching away an area of the active layer, which is not covered with the anti-etching layer pattern, to form an active layer pattern, and reserving the anti-etching layer pattern; and fabricating a source and a drain of the thin film transistor.

Optionally the anti-etching layer pattern is a first photoresist layer pattern doped with the electrically conductive medium.

Optionally fabricating the source and the drain of the thin film transistor includes: covering the anti-etching layer pattern with a source and drain metal layer; fabricating a second photoresist layer pattern on the source and drain metal layer; and etching an area of the source and drain metal layer, which is not covered with the second photoresist layer pattern to form the source and the drain.

Optionally after etching the area of the source and drain metal layer, which is not covered with the second photoresist layer pattern to form the source and the drain, the method further includes: stripping away both an area of the anti-etching layer pattern, which is not covered with the source and the drain, and the second photoresist layer pattern.

Optionally photoresist for the first photoresist layer pattern and the second photoresist layer pattern is made of a same material.

Optionally stripping away both the area of the anti-etching layer pattern, which is not covered with the source and the drain, and the second photoresist layer pattern includes: stripping away both the area of the anti-etching layer pattern, which is not covered with the source and the drain, and the second photoresist layer pattern in the same stripping process using photoresist striping solution.

Optionally before fabricating the source and the drain of the thin film transistor, the method further includes: thinning the anti-etching layer pattern.

Optionally the thickness of the thinned anti-etching layer pattern is kept between 100 nm and 500 nm.

Optionally the material of the active layer is a metal oxide material.

Optionally the electrically conductive medium is selected from at least one of metal particles, electrically conductive alloy particles, metal oxide particles, and non-metal electrically conductive particles.

Optionally the electrically conductive medium comprises nanometer grapheme.

Optionally in a case of that the anti-etching layer pattern is a first photoresist layer pattern doped with the electrically conductive medium, fabricating the anti-etching layer pattern on the active layer will include: coating a thin film of a first photoresist layer material doped with the electrically conductive medium on the active layer, and then heating and curing the thin film into a first photoresist layer; and forming the anti-etching layer pattern at the first photoresist layer.

An embodiment of this disclosure provides a thin film transistor including: an underlying substrate, and a gate, an active layer, a source, and a drain, all of which are located on the underlying substrate, wherein the source and the drain are located above the active layer, and the thin film transistor further includes: an anti-etching layer located between the active layer and the source, and an anti-etching layer located between the active layer and the drain; and both of anti-etching layers are doped with an electrically conductive medium, the source and the drain are electrically connected with the active layer respectively through each of the anti-etching layers, and the anti-etching layer located between the active layer and the source is spaced from the anti-etching layer located between the active layer and the drain.

Optionally an orthographic projection of the source onto the underlying substrate overlies an orthographic projection of the anti-etching layer located below the source onto the underlying substrate; and an orthographic projection of the drain onto the underlying substrate overlies an orthographic projection of the anti-etching layer located below the drain onto the underlying substrate

Optionally the anti-etching layer is a photoresist layer doped with the electrically conductive medium.

Optionally the thickness of the anti-etching layer ranges from 100 to 500 nm.

Optionally the material of the active layer is a metal oxide material.

Optionally the electrically conductive medium is selected from at least one of metal particles, electrically conductive alloy particles, metal oxide particles and non-metal electrically conductive particles.

Optionally the electrically conductive medium includes a nanometer grapheme.

An embodiment of this disclosure provides an array substrate including the thin film transistor according to any one of the embodiments above of this disclosure.

An embodiment of this disclosure provides a display device including the array substrate according to the embodiment above of this disclosure.

### BRIEF DESCRIPTION OF THE DRAWINGS

In order to make the technical solutions according to embodiments of this disclosure more apparent, the drawings to which reference is made in the description of the embodiments will be introduced briefly, and apparently the drawings to be described below are only some embodiments of this disclosure, and those ordinarily skilled in the art can further derive other drawings from these drawings here without any inventive effort.

FIG. 1 is a schematic diagram of steps in a method for fabricating a thin film transistor according to an embodiment of this disclosure.

FIG. 2 is a first schematic structural diagram of a thin film transistor according to an embodiment of this disclosure.

FIG. 3 is a second schematic structural diagram of a thin film transistor according to an embodiment of this disclosure.

FIG. 4 is a third schematic structural diagram of a thin film transistor according to an embodiment of this disclosure.

FIG. 5 is a fourth schematic structural diagram of a thin film transistor according to an embodiment of this disclosure.

FIG. 6 is a fifth schematic structural diagram of a thin film transistor according to an embodiment of this disclosure.

FIG. 7 is a sixth schematic structural diagram of a thin film transistor according to an embodiment of this disclosure.

FIG. 8 is a seventh schematic structural diagram of a thin film transistor according to an embodiment of this disclosure.

FIG. 9 is an eighth schematic structural diagram of a thin film transistor according to an embodiment of this disclosure.

FIG. 10 is a ninth schematic structural diagram of a thin film transistor according to an embodiment of this disclosure.

FIG. 11 is a tenth schematic structural diagram of a thin film transistor according to an embodiment of this disclosure.

FIG. 12 is a schematic flow chart of details of fabricating a thin film transistor according to an embodiment of the disclosure.

### DETAILED DESCRIPTION OF THE EMBODIMENTS

In order to make the objects, technical solutions, and advantages of this disclosure more apparent, this disclosure will be described below in further details with reference to the drawings, and apparently the embodiments to be described are only a part but not all of the embodiments of this disclosure. Based upon the embodiments here of this disclosure, all the other embodiments which can occur to those ordinarily skilled in the art without any inventive effort shall fall into the scope of the disclosure as claimed.

FIG. 1 illustrates a method for fabricating a thin film transistor according to an embodiment of this disclosure, where the method includes the following steps.

The step 101 is to fabricate an anti-etching layer pattern on an active layer, where the anti-etching layer pattern is doped with an electrically conductive medium.

The step 102 is to etch away an area of the active layer, which is not covered with the anti-etching layer pattern, to form an active layer pattern, and to reserve the anti-etching layer pattern.

The step 103 is to fabricate a source and a drain of the thin film transistor.

In some embodiments of this disclosure, the anti-etching layer pattern doped with the electrically conductive medium is fabricated above the active layer, and then the source and the drain are formed, that is, the anti-etching layer is arranged between the active layer, and the source and drain, and the electrically conductive medium with a lower resistivity doped in the anti-etching layer pattern can increase the electrical contact area between the active layer and the source and drain, and lower the contact resistance at the interfaces between the active layer and the source and drain, so that a good electrical contact area can be formed between the source and the active layer, and between the drain and the active layer to thereby improve the electrical connectivity of the thin film transistor.

Optionally in some embodiments of the disclosure, the material of the active layer is a metal oxide material. The active layer in some embodiments of the disclosure can be Indium Gallium Zinc Oxide (IGZO), Indium Zinc Oxide (IZO), indium oxide (In₂O₃):molybdenum (Mo) (molybdenum doped indium oxide), Zinc Oxide (ZnO):Aluminium (Al) (aluminium doped zinc oxide), TiO₂:Nb (niobium doped titanium dioxide), (tin cadmium tin oxide) (Cd—Sn—O), or another metal oxide.

The electrically conductive medium in some embodiments of this disclosure can be an electrically conductive medium with a low resistivity (e.g., an electrically conductive medium with a resistivity below 10*10−8 ohm*meter (Ω*m)), and for example, the electrically conductive medium can be nickel (e.g., nickel nanometer particles), silver (e.g., silver nanometer particles), copper, or other metal particles or fibers, can be a copper alloy, an aluminium alloy, or other electrically conductive alloy particles, or can be IGZO, In₂O₃, or other electrically conductive metal oxide particles, or can be carbon (e.g., carbon nanometer particles or fibers, where the carbon nanometer particles can be hollow carbon particles, solid carbon sphere particles, carbon sphere particles in a kernel structure, glue encapsulated carbon sphere particles, etc., and the carbon nanometer fibers include acrylonitrile based fibers carbon, asphalt based carbon fibers, etc.), boron, silicon, graphite, and other non-metal electrically conductive particles. Furthermore the electrically conductive medium can alternatively include a part or all of electrically conductive metal particles, electrically conductive alloy particles, and non-metal electrically conductive particles.

Here the electrically conductive medium can be embodied as silver, copper, and other metal particles or electrically conductive metal oxide particles with a stable chemical characteristic and a high electrically conductivity, and since there is a more stable chemical characteristic of the metal particles or the electrically conductive metal oxide particles, a contact resistance can be further prevented from being formed at the interface of the metal particles with the source and/or the drain, to thereby lower the contact resistance at the interface so as to improve the electrical connectivity of the thin film transistor; and furthermore the electrically conductive medium can be embodied as doping non-metal electrically conductive particles to thereby avoid the electrically conductive medium from being oxidized, so as to further lower the contact resistance, and to improve the electrical connectivity of the thin film transistor. Furthermore the doping electrically conductive medium in some embodiments of this disclosure can be a nanometer-level conductive medium to thereby further increase the contact area at the interface, and lower the formed contact resistance.

In some embodiments of this disclosure, the anti-etching layer pattern is fabricated on the active layer, and since the active layer of the thin film transistor is made of metal oxide sensitive to etchant solution, the anti-etching layer pattern can be made of an anti-etching material on the active layer to thereby prevent the active layer from being eroded by the etchant solution while the source and the drain are being formed through etching, which would otherwise damage the active layer and thus degrade the performance of the thin film transistor, where the anti-etching layer pattern can be fabricated as the anti-etching layer doped with the electrically conductive medium, and for example, can be made of photoresist doped with metal particles.

The anti-etching layer pattern located on the active layer can protect the active layer while the source and the drain are being formed through etching, to thereby prevent the active layer from being damaged in the patterning process, so as to improve the performance stability of the active layer of the thin film transistor, thus guaranteeing the performance stability of the fabricated thin film transistor. Furthermore the anti-etching layer pattern is doped with the electrically conductive medium, and the source and the drain are electrically connected with the active layer through the anti-etching layer, so that the contact resistance at the interfaces between the active layer and the source and drain can be lowered.

Optionally the electrically conductive medium includes nanometer grapheme.

In some embodiments of this disclosure, the electrically conductive medium doped in the anti-etching layer pattern can be embodied as nanometer grapheme, and for example, the anti-etching layer pattern can be doped with seamless and hollow electrically conductive carbon nanotubes, which are formed by rolling grapheme sheets and include single-wall carbon nanotubes, dual-wall carbon nanotubes, multi-wall carbon nanotubes, etc., where the grapheme has an electron mobility (15000 cm²/(V*s) (square centimeter per volt·second), which is 100 times that of silicon, and an electrical conductivity of up to 7200S/cm (Siemens per centimeter), so there will be a high electrical conductivity of the anti-etching layer pattern doped with the electrically conductive medium in some embodiments of this disclosure, which is made of grapheme, thus further lowering the contact resistance between the source and the active layer, and the contact resistance between the drain and the active layer. Furthermore the grapheme also has an ultra-high theoretical surface area per gram (2630 m²/g) (square meter per gram), a high thermal conductivity (5000 W/m*K) (watt per meter·degree), a high pressure (130 GPa), a high modulus (1060 Gpa), and a low fabrication cost.

Since the grapheme has the characteristic of a high theoretical surface area per gram, the contact area at the interfaces between the anti-etching layer pattern doped with the grapheme, and the source and drain metal can be further increased to thereby further improve the electrical connectivity of the thin film transistor. Furthermore the nanometer-level grapheme can further increase the contact area at the interface between the source and drain metal.

Optionally the anti-etching layer pattern is a first photoresist layer pattern doped with the electrically conductive medium, so that the anti-etching layer can be reused as a photoresist layer for forming the active layer, to thereby simplify the fabrication process.

In some embodiments of this disclosure, if the anti-etching layer pattern is a first photoresist layer pattern doped with the electrically conductive medium, then the anti-etching layer pattern can be fabricated on the active layer by coating a thin film of a first photoresist layer material doped with the electrically conductive medium on the active layer, and then heating and curing the thin film into a first photoresist layer; and forming the anti-etching layer pattern at the first photoresist layer.

Optionally in some embodiments of this disclosure, the gate can be formed before the active layer is formed, that is, the thin film transistor is structured with a bottom gate. Of course, the gate can alternatively be formed after the active layer is formed, that is, the thin film transistor is structured with a top gate, although some embodiments of this disclosure will not be limited thereto.

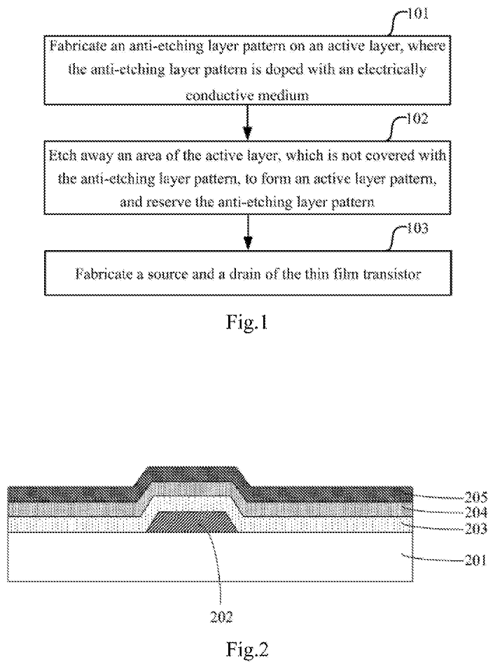

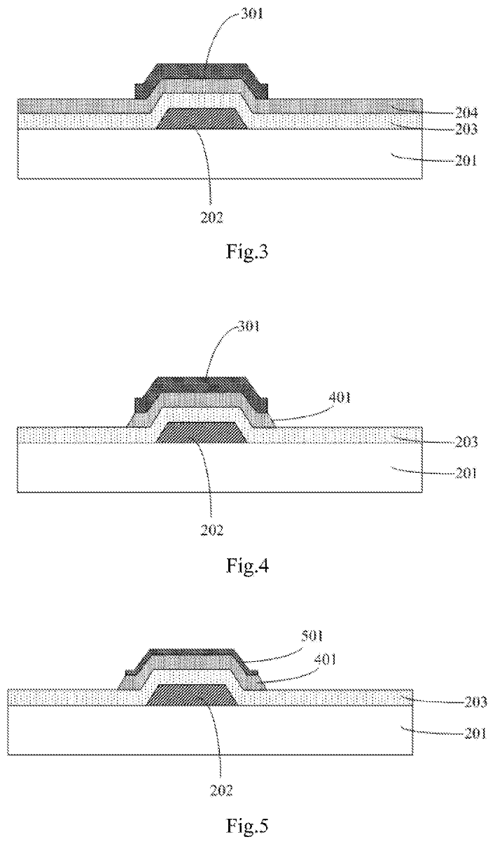

Optionally, the thin film transistor is structured with a bottom gate, where a gate 202, a gate insulation layer 203, an active layer 204, and an anti-etching layer 205 made of photoresist doped with the electrically conductive medium are formed on an underlying substrate 201 in that order as illustrated in FIG. 2. Optionally the anti-etching layer 205 can be fabricated by coating an electrically conductive photoresist thin film, with the thickness of 0.2 to 2.0 micrometers (μm), of the electrically conductive medium, a film formation resin, a photosensitive agent, a solvent, and an additive, and heating and curing the electrically conductive photoresist thin film under some temperature conditional for some period of time into an electrically conductive photoresist layer, which is the anti-etching layer 205; and thereafter an electrically conductive photoresist layer pattern in some pattern can be fabricated at the electrically conductive photoresist layer, and FIG. 3 illustrates the fabricated electrically conductive photoresist layer pattern as an anti-etching layer pattern 301, where the film formation resin is a thermoplastic resin, the photosensitive agent is an aromatic keto derivative or a benzoin ether derivative, and the film formation resin, the photosensitive agent, the solvent, and the additive can be common components for fabricating a photoresist layer in the art.

For example, the electrically conductive photoresist thin film, with the thickness of 1.5 μm, of the electrically conductive medium, the film formation resin, the photosensitive agent, the solvent, and the additive is coated, and then heated and cured at temperature of 100 to 110° C. for 60 seconds, and thereafter exposed and developed into the electrically conductive photoresist layer pattern in some pattern.

Moreover the anti-etching layer can be made of the epoxy resin, the phenolic resin, the acrylic acid resin, or the like, doped with the electrically conductive medium.

Furthermore the anti-etching layer pattern in some embodiments of this disclosure can prevent metal elements in the source and the drain from being diffused into the active layer while the thin film transistor is being fabricated, to thereby prevent the active layer semiconductor from failing due to the diffused metal elements, so as to improve the performance of the thin film transistor.

Optionally the metal oxide is etched into the active layer pattern by etching an area of the active layer, which is not covered with the anti-etching layer pattern through wet etching to form the active layer pattern.

In some embodiments of this disclosure, the active layer pattern can be formed at the active layer through wet etching in which a material to be etched is dipped in the etchant solution and eroded. For example, the area of the active layer 204, which is not covered with the anti-etching layer pattern 301 in FIG. 3, can be etched using phosphoric acid, nitric acid, acetic acid, or another etchant solution to form an active layer pattern 401 in FIG. 4.

Optionally the anti-etching layer pattern is thinned before the source and the drain of the thin film transistor are fabricated.

Optionally the thickness of the thinned anti-etching layer pattern is kept between 100 nm and 500 nm.

In some embodiments of this disclosure, before the source and the drain of the thin film transistor are fabricated, the anti-etching layer pattern can be thinned to thereby adjust the thickness of the anti-etching layer pattern, and for example, the anti-etching layer pattern 301 made of the photoresist in FIG. 3 can be thinned in an ashing process to form an anti-etching layer pattern 501 in FIG. 5 with the thickness thereof kept between 100 to 500 nanometers (nm). The anti-etching layer pattern with such a thickness can prevent the active layer pattern from being eroded by the etchant solution while the source and the drain are being etched, and also the anti-etching layer pattern with such a thickness can be easily stripped away to thereby prevent a short-circuit condition from being created between the formed source and drain through the electrically conductive anti-etching layer pattern.

Optionally the source and the drain of the thin film transistor are fabricated by covering the anti-etching layer pattern with a source and drain metal layer; fabricating a second photoresist layer pattern above the source and drain metal layer; and etching an area of the source and drain metal layer, which is not covered with the second photoresist layer pattern to form the source and the drain.

In some embodiments of this disclosure, if the anti-etching layer pattern is a photoresist layer pattern doped with the electrically conductive medium, then after the anti-etching layer pattern is covered with the source and drain metal layer, the second photoresist layer pattern can be made of second photoresist, and thereafter the source and drain metal layer can be etched to form the source and the drain, where the second photoresist layer pattern is located above the source and drain metal layer, and the source and drain metal layer can be made of chrome (Cr), tungsten (W), copper (Cu), titanium (Ti), tantalum (Ta), Mo, or another metal, or an alloy thereof; and the thickness of the source and drain metal layer can range from 200 to 1000 nm, and can be structured in one or more layers of the materials above.

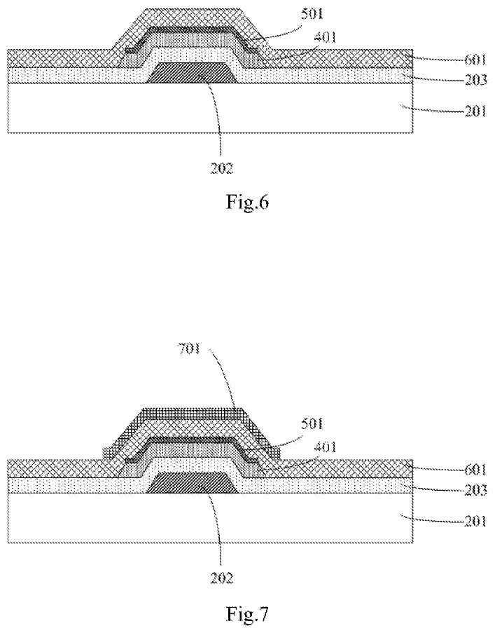

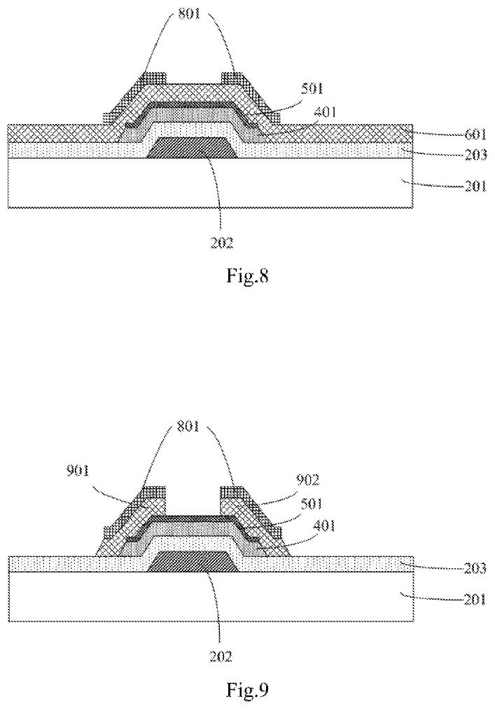

Optionally after the metal oxide is etched into the active layer pattern, the anti-etching layer pattern is covered with the source and drain metal layer, and for example, the anti-etching layer pattern 501 illustrated in FIG. 5 is covered with the source and drain metal layer to form a source and drain metal layer 601 illustrated in FIG. 6 for forming the source and the drain through etching; a second photoresist layer for fabricating the second photoresist layer pattern is formed on the source and drain metal layer, and for example, the source and drain metal layer 601 in FIG. 6 is covered with a thin film of photoresist, and heated and cured into a second photoresist layer 701 as illustrated in FIG. 7; the second photoresist layer is exposed, developed, etc., into the second photoresist layer pattern, and for example, the second photoresist layer 701 in FIG. 7 is exposed and developed into a second photoresist layer pattern 801 in FIG. 8; and the area of the source and drain metal layer, which is not covered with the second photoresist layer pattern is etched to form the source and the drain, and for example, the second photoresist layer pattern 801 in FIG. 8 is etched to form a source 901 and a drain 902 in FIG. 9.

Optionally both an area of the anti-etching layer pattern, which is not covered with the source and the drain, and the second photoresist layer pattern are stripped away, after the area of the source and drain metal layer, which is not covered with the second photoresist layer pattern, is etched.

Optionally the photoresist for the first photoresist layer pattern and the second photoresist layer pattern is made of the same material.

In some embodiments of this disclosure, there is the electrically conductive anti-etching layer pattern on the active layer, so that a short-circuit condition may be created between the source and the drain directly through the electrically conductive anti-etching layer pattern, thus making the thin film transistor fail to operate normally, so it is necessary to strip away the area of the anti-etching layer pattern, which is not covered with the source and the drain. Since the photoresist for the first photoresist layer pattern and the second photoresist layer pattern is made of the same material, both the area of the anti-etching layer pattern, which is not covered with the source and the drain, and the second photoresist layer pattern can be stripped away in the same stripping process after the source and the drain are fabricated, to thereby reduce the number of process steps of fabricating the thin film transistor so as to improve the production efficiency, and to lower the product cost.

For example, both the second photoresist layer pattern, and the first photoresist layer pattern in the anti-etching layer pattern can be made of the same photoresist material, so both the area of the anti-etching layer pattern, which is not covered with the source and the drain, and the second photoresist layer pattern can be stripped away in the same stripping process using the same striping solution.

Optionally both the second photoresist layer pattern, and the first photoresist layer pattern in the anti-etching layer pattern can be made of the same photoresist material, so both the area of the anti-etching layer pattern, which is not covered with the source and the drain, and the second photoresist layer pattern are stripped away in the same stripping process by stripping away the area of the anti-etching layer pattern, which is not covered with the source and the drain, and the second photoresist layer pattern using photoresist stripping solution.

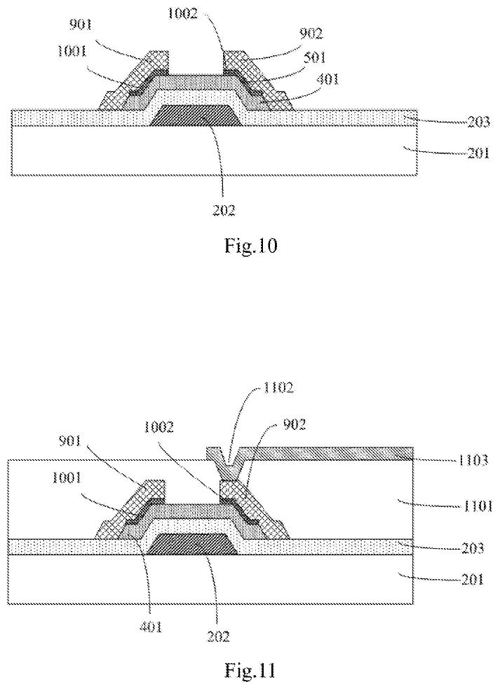

In some embodiments of this disclosure, the anti-etching layer pattern can be a photoresist layer pattern doped with the electrically conductive medium, and the second photoresist layer pattern can be a photoresist layer pattern, so both the area of the anti-etching layer pattern, which is not covered with the source and the drain, and the second photoresist layer pattern can be stripped away in the same stripping process. For example, both the anti-etching layer pattern 501 and the second photoresist layer pattern 801 in FIG. 9 are made of photoresist, so both the area of the anti-etching layer pattern 501, which is not covered with the source and the drain, and the second photoresist layer pattern 801 can be stripped away in the same stripping process using the same photoresist stripping solution, and a source active layer contact area 1001, and a drain and active layer contact area 1002 in FIG. 10 can be formed in the anti-etching layer pattern 501 after the area thereof which is not covered with the source and the drain is stripped away.

Optionally after the source and the drain of the thin film transistor are fabricated, a passivation layer with a through-hole is fabricated; and a transparent pixel electrode is fabricated on the passivation layer so that the pixel electrode is connected with the source or the drain through the through-hole.

In some embodiments of this disclosure, the substrate of the thin film transistor after the source and the drain are fabricated is covered with the passivation layer, the through-hole is formed on the passivation layer, a transparent electrically conductive layer is grown on the passivation layer, and a transparent pixel electrode is fabricated from the transparent electrically conductive layer, so that the transparent pixel electrode is connected with the source or the drain through the through-hole. For example, a thin film transistor as illustrated in FIG. 10 can be covered with a passivation layer, a passivation layer 1101 as illustrated in FIG. 11 can be formed, a through-hole 1102 can be fabricated on the passivation layer 1101, and thereafter a pixel electrode 1103 can be fabricated at the passivation layer 1101, so that the pixel electrode 1103 is connected with a drain 902 through the through-hole 1102.

Optionally the passivation layer with the thickness of 200 to 600 nm can be formed through Plasma Enhanced Chemical Vapor Deposition; the through-hole of the passivation layer can be formed in a patterning process, and thereafter a transparent electrically conductive layer can be deposited and grown on the passivation layer through magnetically controlled spraying; and the pixel electrode can be fabricated from the electrically conductive layer in a patterning process, so that the transparent pixel electrode is connected with the source or the drain through the through-hole, where the passivation layer can be fabricated in a single layer of silicon nitride, a compound structure of silicon oxide and silicon nitride, or three layers of silicon nitride, silicon oxynitride, and silicon nitride; and the transparent electrically conductive layer can be indium tin oxide (ITO), IZO, or another transparent metal oxide, and the thickness of the fabricated transparent pixel electrode ranges from 40 to 80 nm.

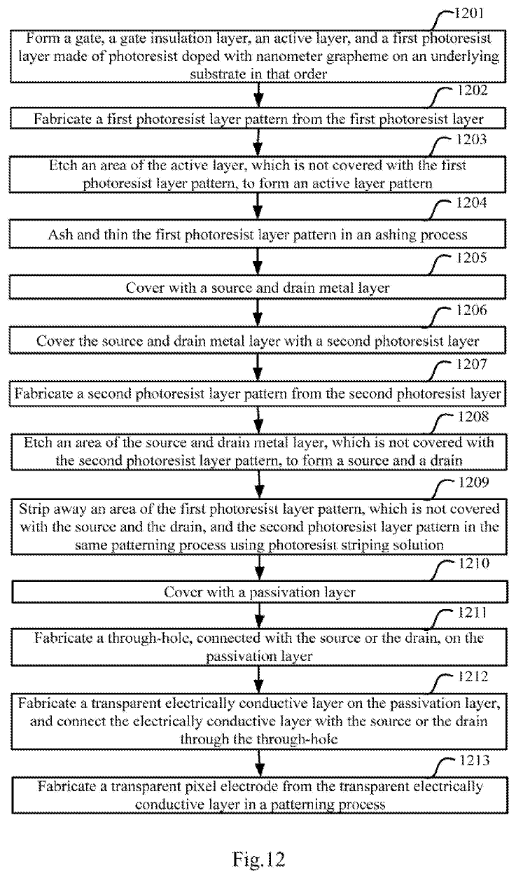

As illustrated in FIG. 12, if the anti-etching layer is the first photoresist layer doped with nanometer grapheme, then a method for fabricating a thin film transistor according to an embodiment of this disclosure will include the following steps.

The step 1201 is to form a gate, a gate insulation layer, an active layer, and a first photoresist layer made of photoresist doped with nanometer grapheme on an underlying substrate in that order.

The step 1202 is to fabricate a first photoresist layer pattern from the first photoresist layer.

The step 1203 is to etch an area of the active layer, which is not covered with the first photoresist layer pattern, to form an active layer pattern.

The step 1204 is to ash and thin the first photoresist layer pattern in an ashing process.

The step 1205 is to cover with a source and drain metal layer.

The step 1206 is to cover the source and drain metal layer with a second photoresist layer.

The step 1207 is to fabricate a second photoresist layer pattern from the second photoresist layer.

The step 1208 is to etch an area of the source and drain metal layer, which is not covered with the second photoresist layer pattern, to form a source and a drain.

The step 1209 is to strip away an area of the first photoresist layer pattern, which is not covered with the source and the drain, and the second photoresist layer pattern in the same patterning process using photoresist striping solution.

The step 1210 is to cover with a passivation layer.

The step 1211 is to fabricate a through-hole, connected with the source or the drain, on the passivation layer.

The step 1212 is to fabricate a transparent electrically conductive layer on the passivation layer, and to connect the electrically conductive layer with the source or the drain through the through-hole.

The step 1213 is to fabricate a transparent pixel electrode from the transparent electrically conductive layer in a patterning process.

Based upon the same idea of this disclosure, an embodiment of the disclosure further provides a thin film transistor, and since the thin film transistor addresses the problem under a similar principle to the method according to some embodiments of this disclosure, reference can be made to the implementation of the method for an implementation of the thin film transistor, and a repeated description thereof will be omitted here.

There is a thin film transistor, which is a thin film transistor fabricated in the method for fabricating a thin film transistor according to some embodiments of this disclosure.

Optionally as illustrated in FIG. 11, a thin film transistor according to an embodiment of this disclosure includes an underlying substrate 201, and a gate 202, an active layer 401, a source 901, and a drain 902, all of which are located on the underlying substrate, where the source 901 and the drain 902 are located above the active layer 401, and the thin film transistor further includes an anti-etching layer 1001 located between the active layer 401 and the source 901, and an anti-etching layer 1002 located between the active layer 401 and the drain 902.

The anti-etching layers (1001 and 1002) are doped with an electrically conductive medium, the source 901 is electrically connected with the active layer 401 through the anti-etching layer 1001, the drain 902 is electrically connected with the active layer 401 through the anti-etching layer 1002, and the anti-etching layer 1001 located between the active layer 401 and the source 901 is spaced from the anti-etching layer 1002 located between the active layer 401 and the drain 902.

In some embodiments of this disclosure, the gate can be located below the active layer, or can be located above the active layer, although some embodiments of this disclosure will not be limited thereto.

The gate is located below the active layer, for example, and in some embodiments of this disclosure, there is further arranged a gate insulation layer 203 between the active layer 401 and the gate 202, the source 901 and the drain 902 are further covered with a passivation layer 1101, and there is further arranged a transparent pixel electrode 1103 on the passivation layer 1101, which is electrically connected with the drain 902 through a through-hole 1102 running through the passivation layer 1101.

Since the anti-etching layers are arranged between the active layer and the source and drain, and the electrically conductive medium with a low resistivity doped in the anti-etching layers can increase the electrical contact area between the active layer and the source and drain, and lower the contact resistance at the interfaces between the active layer and the source and drain, a good electrical contact area can be formed between the source and the active layer, and between the drain and the active layer to thereby improve the electrical connectivity of the thin film transistor.

Optionally as illustrated in FIG. 11, an orthographic projection of the source 901 onto the underlying substrate 201 overlies an orthographic projection of the anti-etching layer 1001 located below the source 901 onto the underlying substrate 201.

An orthographic projection of the drain 902 onto the underlying substrate 201 overlies an orthographic projection of the anti-etching layer 1002 located below the drain 902 onto the underlying substrate 201.

Optionally the anti-etching layers are photoresist layers doped with the electrically conductive medium, so that the anti-etching layers can be used as a photoresist layer for fabricating the active layer while the thin film transistor is being fabricated, to thereby simplify the fabrication process.

Optionally the thicknesses of the anti-etching layers range from 100 to 500 nm.

Optionally the material of the active layer is a metal oxide material.

Optionally the electrically conductive medium is selected from at least one of metal particles, electrically conductive alloy particles, metal oxide particles; and non-metal electrically conductive particles.

Optionally the electrically conductive medium includes a nanometer grapheme.

Based upon the same idea of this disclosure, an embodiment of the disclosure further provides an array substrate, and since the array substrate addresses the problem under a similar principle to that of the thin film transistor according to some embodiments of this disclosure, reference can be made to the implementation of the array substrate for an implementation of the thin film transistor, and a repeated description thereof will be omitted here.

There is an array substrate including the thin film transistor according to some embodiments of this disclosure.

Based upon the same idea of this disclosure, an embodiment of this disclosure further provides a display device, and since the display device addresses the problem under a similar principle to that of the array substrate according to some embodiments of this disclosure, reference can be made to the implementation of the array substrate for an implementation of the display device, and a repeated description thereof will be omitted here.

There is a display device including the array substrate according to some embodiments of this disclosure.

In some embodiments of this disclosure, the display device can be a mobile phone, a tablet computer, a TV set, a monitor, a notebook computer, a digital photo frame, a navigator, or any other product or component with a display function.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. A method for fabricating a thin film transistor, the method comprises:
fabricating an anti-etching layer pattern on an active layer, wherein the anti-etching layer pattern is doped with an electrically conductive medium;
etching away an area of the active layer, which is not covered with the anti-etching layer pattern, to form an active layer pattern, and reserving the anti-etching layer pattern; and
fabricating a source and a drain of the thin film transistor.

2. The method according to claim 1, wherein the anti-etching layer pattern is a first photoresist layer pattern doped with the electrically conductive medium.

3. The method according to claim 2, wherein fabricating the source and the drain of the thin film transistor comprises:
covering the anti-etching layer pattern with a source and drain metal layer;
fabricating a second photoresist layer pattern on the source and drain metal layer; and
etching an area of the source and drain metal layer, which is not covered with the second photoresist layer pattern to form the source and the drain.

4. The method according to claim 3, wherein after etching the area of the source and drain metal layer, which is not covered with the second photoresist layer pattern to form the source and the drain, the method further comprises:
stripping away both an area of the anti-etching layer pattern, which is not covered with the source and the drain, and the second photoresist layer pattern.

5. The method according to claim 4, wherein photoresist for the first photoresist layer pattern and the second photoresist layer pattern is made of a same material.

6. The method according to claim 5, wherein stripping away both the area of the anti-etching layer pattern, which is not covered with the source and the drain, and the second photoresist layer pattern comprises:
stripping away both the area of the anti-etching layer pattern, which is not covered with the source and the drain, and the second photoresist layer pattern in a same stripping process using a photoresist striping solution.

7. The method according to claim 1, wherein before fabricating the source and the drain of the thin film transistor, the method further comprises:
thinning the anti-etching layer pattern.

8. The method according to claim 7, wherein a thickness of thinned anti-etching layer pattern is kept between 100 nm and 500 nm.

9. The method according to claim 1, wherein a material of the active layer is a metal oxide material.

10. The method according to claim 1, wherein the electrically conductive medium is selected from at least one of metal particles, electrically conductive alloy particles, metal oxide particles, and non-metal electrically conductive particles; the non-metal electrically conductive particles comprises a nanometer grapheme.

11. (canceled)

12. The method according to claim 10, wherein in a case of that the anti-etching layer pattern is a first photoresist layer pattern doped with the electrically conductive medium, fabricating the anti-etching layer pattern on the active layer will comprise:
coating a thin film of a first photoresist layer material doped with the electrically conductive medium on the active layer, and then heating and curing the thin film into a first photoresist layer; and
forming the anti-etching layer pattern at the first photoresist layer.

13. A thin film transistor, comprising: an underlying substrate, and a gate, an active layer, a source, and a drain, all of which are located on the underlying substrate, wherein the source and the drain are located above the active layer, and the thin film transistor further comprises:
an anti-etching layer located between the active layer and the source, and an anti-etching layer located between the active layer and the drain; and
both of anti-etching layers are doped with an electrically conductive medium, the source and the drain are electrically connected with the active layer respectively through each of the anti-etching layers, and the anti-etching layer located between the active layer and the source is spaced from the anti-etching layer located between the active layer and the drain.

14. The thin film transistor according to claim 13, wherein an orthographic projection of the source onto the underlying substrate overlies an orthographic projection of the anti-etching layer located below the source onto the underlying substrate; and
an orthographic projection of the drain onto the underlying substrate overlies an orthographic projection of the anti-etching layer located below the drain onto the underlying substrate

15. The thin film transistor according to claim 13, wherein the anti-etching layer is a photoresist layer doped with the electrically conductive medium.

16. The thin film transistor according to claim 13, wherein a thickness of the anti-etching layer ranges from 100 to 500 nm.

17. The thin film transistor according to claim 13, wherein a material of the active layer is a metal oxide material.

18. The thin film transistor according to claim 13, wherein the electrically conductive medium is selected from at least one of metal particles, electrically conductive alloy particles, metal oxide particles and non-metal electrically conductive particles.

19. The thin film transistor according to claim 3, wherein the electrically conductive medium comprises a nanometer grapheme.

20. An array substrate, comprising the thin film transistor according to claim 13.

21. A display device, comprising the array substrate according to claim 20.
